(19) United States
(12) Patent Application Publication
(10) Pub. No.: US 2008/0151200 A1
(43) Pub. Date: Jun. 26, 2008

(54) Exposure Apparatus and Device Manufacturing Method

(75) Inventor: Hiroaki Takaiwa, Saitama-ken (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 10/589,665

(22) PCT Filed: Feb. 17, 2005
(86) PCT No.: PCT/JP05/02444

§ 371 Date: Aug. 16, 2006

(30) Foreign Application Priority Data
Feb. 19, 2004 (JP) 2004-043114

(51) Int. Cl. G03B 27/42; G03F 7/20

(52) U.S. Cl. 355/30; 430/322

(57) ABSTRACT

An exposure apparatus (EX) has an exposure region (E) for irradiating exposure light (EL) to a substrate (W) through an optical system (30) and liquid (LQ) and has a measurement region (A) for acquiring information on the position of the substrate (W) prior to the exposure. The substrate (W) is exposed when moved between the exposure region (E) and the measurement region (A). The exposure apparatus (EX) has an entry shutoff mechanism (60) for preventing a gas (G) in the vicinity of the exposure region (E) from entering into the measurement region (A).

### BACKGROUND OF THE INVENTION

1. Field of the Invention

The present invention relates to an exposure apparatus used in the transfer process among the lithography processes for the manufacture of highly integrated semiconductor circuit elements. The present application asserts priority rights with respect to Japanese Patent Application No. 2004-43114 applied for on Feb. 19, 2004, and the present application is hereby incorporated by reference in its entirety.

2. Description of the Related Art

A semiconductor device or a liquid crystal display device is manufactured by the technique known as photolithography, in which a pattern formed on a mask is transferred onto a photosensitive substrate. The exposure apparatus used in this photolithography process has a mask stage that supports a mask and a substrate stage that supports a substrate, and it transfers the pattern of the mask to a substrate via a projection optical system while sequentially moving the mask stage and the substrate stage. In recent years, higher resolutions for projection optical systems have been in demand to deal with further high integration of device patterns. The shorter the exposure wavelength used and the larger the number of apertures of the projection optical system, the higher the resolution of the projection optical system becomes. For this reason, the exposure wavelengths used in exposure apparatuses are becoming shorter each year, and the number of apertures of projection optical systems is also increasing. In addition, the mainstream exposure wavelength at present is the 248 nm of a KrF excimer laser, but a shorter wavelength, the 193 nm of an ArF excimer laser, is also coming into practical application. In addition, when exposure is performed, the depth of focus (DOF) is also important as well as the resolution. The resolution Re and the depth of focus δ are expressed by the respective equations below.

R=k₁·λ/NA (1)

δ=±k₂·λ/NA² (2)

Here, λ is the exposure wavelength, NA is the number of apertures of the projection optical system, and k₁ and k₂ are process coefficients. Based on Equation (1) and Equation (2), it is apparent that when the exposure wavelength λ is made shorter and increases the number of apertures NA in order to increase the resolution Re, the depth of focus δ becomes narrower.

When the depth of focus δ becomes too narrow, it becomes difficult to match the substrate surface to the image plane of the projection optical system, and there is concern that the margin during the exposure operation will be inadequate. Therefore, the liquid immersion method disclosed in Patent Document 1 below, for example, has been proposed as a method of practically shortening the exposure wavelength and widening the depth of focus. This liquid immersion method fills the space between the lower surface of the projection optical system and the substrate surface with a liquid such as water or an organic solvent, and it uses the fact that the wavelength of the exposure light in liquid becomes 1/n of that in the air (n is the refractive index of the liquid which is normally approximately 1.2˜1.6) to increase the resolution as well as to expand the depth of focus by approximately n times. The disclosure of the following pamphlet is hereby incorporated by reference in its entirety to the extent permitted by the national laws and regulations of the designated states (or elected states) designated by the present international patent application.

Patent Document 1: PCT International Publication No. WO99/49504

Here, in the aforementioned liquid immersion exposure apparatus, liquid is arranged between the lower surface of the projection optical system and the substrate surface, so the humidity surrounding the substrate tends to fluctuate, and, due to this, there is a problem in that the wavelength of the measurement light irradiated from the laser interferometer that measures the substrate position is unstable, and measurement error occurs. In particular, in a so-called twin stage type exposure apparatus, which comprises two tables that hold the substrate and which moves between a region for performing exposure and a region for performing alignment processing, there is a need to prevent the occurrence of laser interferometer measurement errors in the alignment processing region. The present invention was devised taking the circumstances discussed above into account, and its purpose is to propose an exposure apparatus and a device manufacturing method that, in a liquid immersion exposure apparatus, are able to prevent fluctuation of the measurement light for substrate position measurement to control the occurrence of measurement error.

### SUMMARY OF THE INVENTION

In the exposure apparatus and device manufacturing method relating to the present invention, the following means have been employed to solve the aforementioned problems.

The first invention is such that, in an exposure apparatus that has an exposure region for irradiating exposure light to a substrate via an optical system and a liquid and a measurement region for obtaining information relating to the position of the substrate in advance of exposure and moves the substrate between the exposure region and the measurement region to perform exposure of the substrate, it comprises a penetration shielding mechanism that prevents the penetration of the gas, which exists in the vicinity of the exposure region, to the measurement region. According to this invention, the gas in the vicinity of the exposure region, in which the humidity tends to fluctuate, does not penetrate the measurement region, so it is possible to accurately measure the substrate position by means of a laser interferometer in the measurement region.

In addition, in those in which the penetration shielding mechanism is an air conditioning system provided on the exposure apparatus, there is no need to newly provide a special apparatus, so it is possible to control increases in apparatus costs.

Also, in those in which the air conditioning system comprises a chamber, which includes an exposure region and a measurement region, and a blower part that makes gas within the chamber to flow from the measurement region toward the exposure region, movement of the gas, which exists in the vicinity of the exposure region, to the measurement region is nearly eliminated, so it is possible to reliably improve the accuracy of the substrate position by the laser interferometer in the measurement region.

In addition, in those in which the blower part comprises an intake port formed on the measurement region side and an exhaust port formed on the exposure region side, it is possible to flow the air, which is supplied from the intake port to the inside of the chamber, from the measurement region to the exposure region and then towards the exhaust port, so it is possible to always supply the measurement region with gas whose humidity and the like has been regulated, and it is also possible to exhaust the gas whose humidity has increased to outside of the chamber without flowing the gas to the measurement region, so it is possible to reliably improve the accuracy of the substrate position by the laser interferometer in the measurement region.

In addition, in those in which the air conditioning system comprises a shielding part that prevents the passage of gas between the exposure region and the measurement region, it is possible to reliably prevent the gas in the vicinity of the exposure region from moving to the measurement region.

In addition, in those in which the shielding part is an air curtain, changing of the shapes of the constituent elements (for example, the substrate stage and the like) within the chamber is not necessary, and it is possible to form the shielding part easily, so it is possible to control increases in apparatus costs.

In addition, in those in which an intake port and an exhaust port are respectively formed in the exposure region and the measurement region, the gas in the vicinity of the exposure region and the gas in the vicinity of the measurement region almost never mix, so it is possible to maintain the gas of the respective regions in the desired condition without the gases being affected with each other.

In addition, an exposure apparatus of a different embodiment of the present invention is such that, in an exposure apparatus that has an exposure region for irradiating exposure light to a substrate via an optical system and a liquid and a measurement region for obtaining information relating to the position of the substrate in advance of exposure, and moves the substrate between the exposure region and the measurement region to perform exposure of the substrate, it comprises an intake part that individually supplies a gas to the exposure region and the measurement region respectively.

In addition, an exposure apparatus of another different embodiment, is such that, in an exposure apparatus that has an exposure region for irradiating exposure light to a substrate via an optical system and a liquid and a measurement region for obtaining information relating to the position of the substrate in advance of exposure, and moves the substrate between the exposure region and the measurement region to perform exposure of the substrate, it comprises an intake part, which supplies a gas to at least one of the exposure region and the measurement region, and an exhaust part which respectively independently exhausts the gas in the vicinity of the exposure region and the gas in the vicinity of the measurement region.

The second invention is such that, in a device manufacturing method that includes a lithography process, the exposure apparatus of the first invention is used in the lithography process. According to this invention, substrate alignment accuracy is improved and pattern exposure in the exposure region is performed well, so it is possible to manufacture high quality devices.

The following effects can be obtained by means of the present invention.

With the first invention, it is possible to accurately perform measurement of the position of the substrate by a laser interferometer in the measurement region, so substrate alignment accuracy improves, and it is possible to perform pattern exposure in the exposure region well.

With the second invention, it is possible to manufacture high quality devices stably and at low cost.

### BRIEF DESCRIPTION OF THE DRAWINGS

FIG. 1 is a schematic drawing that shows the configuration of an exposure apparatus EX.

FIG. 2 is a schematic drawing that shows the details of the wafer stage system 100.

FIG. 3 is a schematic drawing that shows the details of the wafer stage system 100.

FIG. 4 is a plan view that shows the air conditioning system 60.

FIG. 5 is a drawing that shows a variation of the air conditioning system 60.

FIG. 6A is a drawing that shows a variation of the air conditioning system 60.

FIG. 6B is a drawing that shows a variation of the air conditioning system 60.

FIG. 7 is a drawing that shows a variation of the air conditioning system 60.

FIG. 8 is a flowchart that shows an example of the semiconductor device manufacturing process.

### DETAILED DESCRIPTION OF THE INVENTION

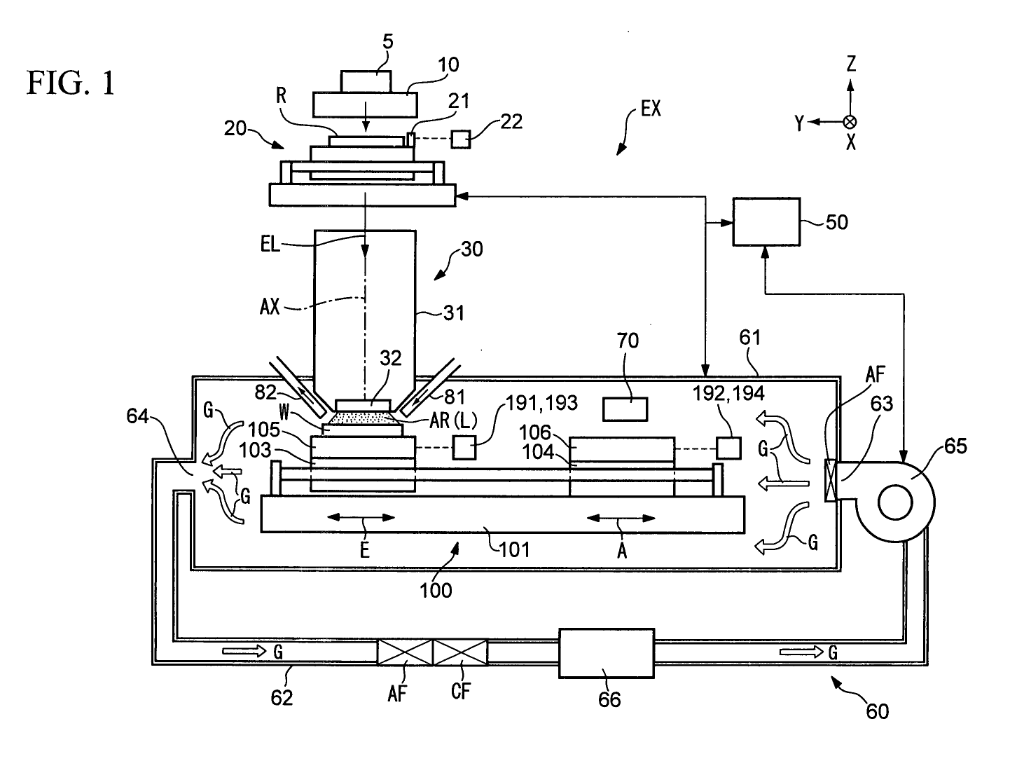

Embodiments of the exposure apparatus and device manufacturing method of the present invention will be explained below while referring to drawings. FIG. 1 is a schematic drawing that shows the configuration of the exposure apparatus of the present invention.

The exposure apparatus EX is a step and scan system scanning type exposure apparatus, that is, a so-called scanning stepper, that synchronously moves a reticle R and a wafer W in one dimensional direction while transferring a pattern formed on the reticle R to the respective shot regions on the wafer W via a projection optical system 30.

Furthermore, the exposure apparatus EX comprises an illumination optical system 10, which illuminates a reticle R by an exposure light EL, a reticle stage 20, which holds the reticle R, a projection optical system 30, which projects the exposure light EL irradiated from the reticle R onto the wafer W, a wafer stage system 100, which holds the wafer W, a control apparatus 50, which comprehensively controls the exposure apparatus EX, and an air conditioning system 60, which controls the gas G in the vicinity of the wafer stage system 100 and the like.

Note that, in the explanation below, the direction that corresponds to the optical axis AX of the projection optical system 30 is the Z axis direction, the synchronous movement direction (scan direction) of the reticle R and the wafer W within a plane perpendicular to the Z axis direction is the Y axis direction, and the direction (non-scan direction) perpendicular to the Z axis direction and the Y axis direction is the X axis direction. Furthermore, the directions around the X axis, Y axis, and the Z axis are the θX, θY and θZ directions respectively.

In addition, the exposure apparatus EX is a liquid immersion exposure apparatus that applies the liquid immersion method to practically shorten the exposure wavelength to improve resolution and to practically broaden the depth of focus, and it comprises a liquid supply apparatus 81 that supplies a liquid L onto the wafer W and a liquid recovery apparatus 82 that recovers the liquid on the wafer W.

Note that, in this embodiment, pure water is used as the liquid L. Pure water is able to transmit, for example, deep ultraviolet light (DUV light) such as ultraviolet range bright lines (g-rays, h-rays, i-rays) that emerge from a mercury lamp or KrF excimer laser light (wavelength of 248 nm), or vacuum ultraviolet light (VUV light) such as ArF excimer laser light (wavelength of 193 nm).

The illumination optical system 10 illuminates a reticle R supported on a reticle stage 20 using exposure light EL and is provided with an exposure light source 5, an optical integrator that uniformize the illumination intensity of the light beam that has emerged from the exposure light source 5, a condenser lens that focuses the exposure light EL from the optical integrator, a relay lens system, and a variable field stop that sets the region of illumination on the reticle R made by the exposure light EL to a slit shape (none of which are shown in the drawings).

The laser beam that emerged from the light source 5 enters the illumination optical system 10, and while the cross-sectional shape of the laser beam is shaped into a slit shape or a rectangular shape (polygon), the laser beam becomes an illumination light (exposure light) EL whose illumination intensity distribution is nearly uniform and is irradiated onto the reticle R.

Note that, for the exposure light EL that emerges from the illumination optical system 10, for example, deep ultraviolet light (DUV light) such as ultraviolet band bright lines (g-rays, h-rays, i-rays) that emerge from a mercury lamp and KrF excimer laser light (wavelength of 248 nm) or vacuum ultraviolet light (VUV light) such as ArF excimer laser light (wavelength of 193 μm) and F₂ laser light (wavelength of 157 nm) are used. In the present embodiment, ArF excimer laser light is used.

The reticle stage 20 supports the reticle R and performs two-dimensional movement within a plane perpendicular to the optical axis AX of the projection optical system 30, that is, within the XY plane and performs slight rotation in the 0 Z direction, and it comprises a reticle fine movement stage, which holds the reticle R, a reticle rough movement stage, which is able to move at the prescribed stroke in the Y axis direction, which is the scan direction, in unison with the reticle fine movement stage, and a linear motor etc. that moves these (none of which are shown in the drawings). In addition, a rectangular aperture is formed on the reticle fine movement stage, and the reticle is held by vacuum suction and the like by means of a reticle suction mechanism provided at the peripheral part of the aperture.

A movable mirror 21 is provided on the reticle stage 20 (reticle fine movement stage). In addition, a laser interferometer 22 is provided at a position that opposes the movable mirror 21. Also, the position and angle of rotation of the reticle R on the reticle stage 20 in the two-dimensional direction is measured in real time by the laser interferometer 22, and the measurement results thereof are output to a control apparatus 50. Then, positioning and the like of the reticle R supported on the reticle stage 20 is performed by the control apparatus 50 driving a linear motor and the like based on the measurement results of the laser interferometer 22.

The projection optical system 30 projection exposes the pattern of the reticle R onto a wafer W at a prescribed projection magnification β, and it comprises a plurality of optical elements, which include an optical element 32 provided at the front end (lower end) part of the wafer W side, and these optical elements are supported by a lens barrel 31. In this embodiment, the projection optical system 30 is a reduction system in which the projection magnification β is ¼ or ⅕, for example. Note that the projection optical system 30 may be either a same magnification system or an enlargement system. Note that the optical element 32 of the front end part of the projection optical system 30 is detachably supported with respect to the lens barrel 31.

The optical element 32 arranged on the lower end of the projection optical system 30 is formed of fluorite. Fluorite has high affinity with water, so it is possible to make the liquid L adhere to nearly the entire liquid contact surface of optical element 32. Specifically, a liquid L (water) that has high affinity with the liquid contact surface of optical element 32 is supplied, so the adhesion between the liquid L and the liquid contact surface of optical element 32 is high, and it is possible to reliably fill the space between optical element 32 and the wafer W with the liquid L. Note that the optical element 32 may be quartz that has high affinity with water. In addition, hydrophilic (lyophilic) treatment may be performed on the liquid contact surface of optical element 32 to further increase affinity with the liquid L.

The wafer stage system 100 comprises two tables (stages), which hold the wafer W, and it is formed so that it alternately moves the wafer W between the region for performing alignment processing of the wafer W (hereunder referred to as the alignment region A) and the region for performing exposure processing (hereunder referred to as the exposure region E).

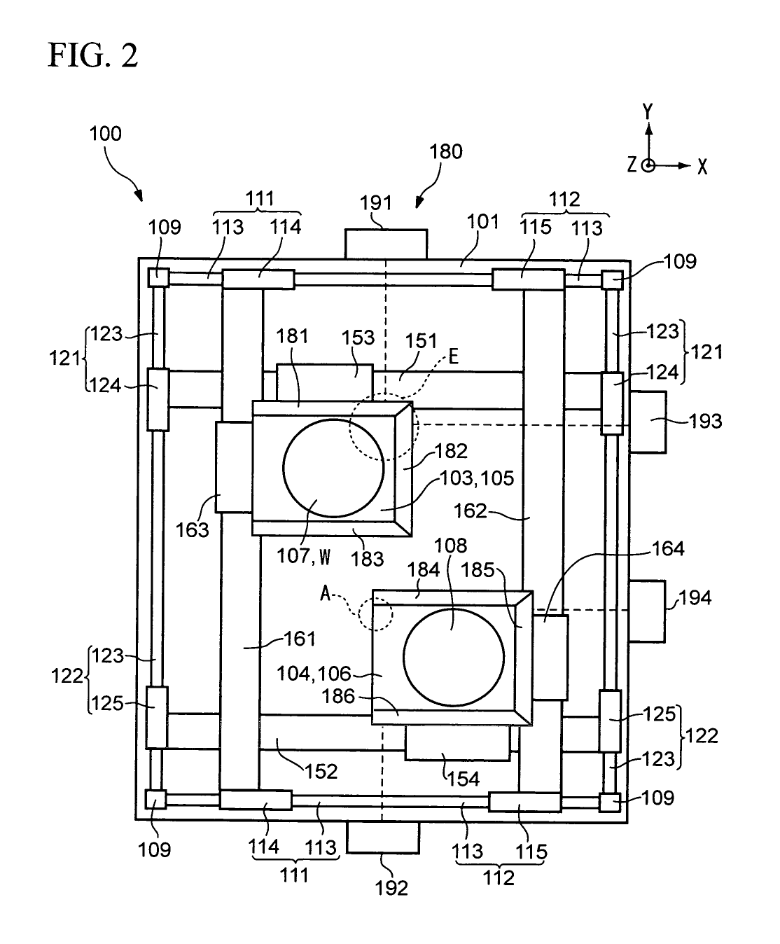

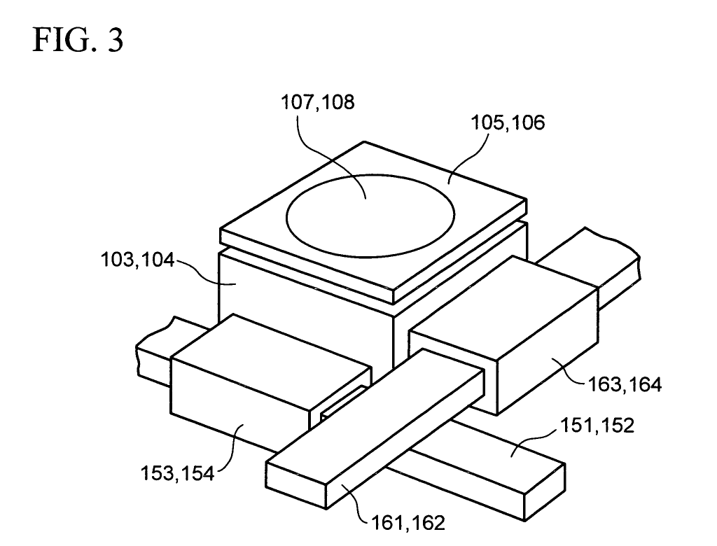

FIG. 2 and FIG. 3 are drawings that show the details of the wafer stage system 100.

The wafer stage system 100 comprises two stages 103 and 104, in which the upper surface of the base plate 101, which is the reference surface of the XY plane, is driven at the prescribed stroke in the X direction and the Y direction. A noncontact bearing (air bearing) which is not shown in the drawings is arranged between the upper surface of the base plate 101 and the stages 103, 104 and is float supported. In addition, as stages 103 and 104 are driven in the X direction by two X linear motors 111, 112, they are driven in the Y direction by two Y linear motors 121, 122. Note that stages 103 and 104 respectively comprise tables 105, 106 on whose upper surface the wafer W is loaded.

X linear motors 111 and 112 share two stators 113 provided to extend approximately in parallel in the X direction, and they comprise a pair of movers 114, 115 respectively provided corresponding to the stators 113. In addition, a pair of movers 114 is linked by a Y guide bar 161 provided to extend in parallel with the Y direction. Similarly, a pair of movers 115 is linked by a Y guide bar 162 provided to extend in parallel with the Y direction. Therefore, X linear motors 111 and 112 are configured so that Y guide bars 161 and 162 are able to move in the X direction, but they are mutually restricted from moving in the X direction, since they share stators 113. Note that stators 113 are supported by the base plate 101 via four motor posts 109.

Y linear motors 121 and 122 share two stators 123 provided to extend approximately in parallel with the Y direction, and they comprise a pair of movers 124, 125 respectively provided corresponding to the stators 123. In addition, a pair of movers 124 is linked by an X guide bar 151 provided to extend in parallel with the X direction. Similarly, a pair of movers 125 is linked by an X guide bar 152 provided to extend in parallel with the X direction. Therefore, Y linear motors 121 and 122 are configured so that X guide bars 151 and 152 are able to move in the Y direction, but they are mutually restricted from moving in the Y direction, since they share stators 123. Note that, in the same way as stators 113, stators 123 are supported on the base plate 101 via four motor posts 109.

X guides 153, 154, which are configured to be able to move in parallel in the X direction along X guide bars 151 and 152 respectively, are provided on X guide bars 151 and 152. Similarly, Y guides 163, 164, which are configured to be able to move in parallel in the Y direction along Y guide bars 161 and 162 respectively, are provided on Y guide bars 161 and 162. Note that X guide bars 151 and 152 and X guides 153 and 154 and Y guide bars 161 and 162 and Y guides 163 and 164 are linked by electromagnetic force.

In addition, one of either X guides 153 or 154 (in FIG. 2, X guide 153) and Y guide 163 are linked to a stage 103. Also, the other X guide 153, 154 (in FIG. 2, X guide 154) and Y guide 164 are linked to a stage 104.

Through the above configuration, tables 105 and 106 (stages 103, 104) are configured so that they are able to move along the intersecting X and Y axes by driving linear motors 111, 112, 121 and 122.

In addition, as shown in FIG. 3, stages 103 and 104, which are formed in cuboids, are linked with X guides 153 and 154 and Y guides 163 and 164. Also, approximately square tables 105 and 106 are arranged at the upper part of stages 103 and 104. In addition, tables 105 and 106 comprise wafer holders 107, 108, which respectively hold the wafer W by suction.

Stages 103 and 104 and tables 105 and 106 are linked via an actuator that is not shown in the drawing, and the configuration is such that, by driving the actuator, it is possible to perform fine movement of tables 105 and 106 in the six directions (degrees of freedom) of the X direction, the Y direction, the Z direction, and the directions around these axes (directions). Note that the actuator may be formed by one or a plurality of rotary motors, voice coil motors, linear motors, electromagnetic actuators or other types of actuators. In addition, the case may also be such that they are configured so that fine movement in the three degrees of freedom of the X direction, the Y direction and the Z direction is possible.

In addition, electromagnetic chucks that are not shown in the drawing are respectively provided on two surfaces (that is, two surfaces that link with X guides 153 and 154) intersecting to the Y direction of the side surfaces of stages 103 and 104. Also, by driving either one of the two (or both) electromagnetic chucks, X guides 153 and 154 and stages 103 and 104 are detachably linked. On the other hand, Y guide 163 and stage 103 and Y guide 164 and stage 104 are linked so that they cannot be detached.

In addition, by combining movement of stages 103 and 104 to the prescribed positions by the respective linear motors 111, 112, 121, 122 and attachment and detachment of guides 153, 154, 163 and 164 with stages 103 and 104 by means of the two electromagnetic chucks, switching of the position between stage 103 and stage 104 is made possible. A stage system which switches the positions of a plurality of stages by such a method is disclosed in, for example, Japanese Patent Application No. 2003-190627.

Note that the means for attaching and detaching X guides 153 and 154 and stages 103 and 104 is not limited to electromagnetic chucks, and it may be, for example, a chuck mechanism that uses air.

Returning to FIG. 2, a measuring system 180, which measures the respective two-dimensional positions (X and Y directions) of tables 105 and 106 is provided on the wafer stage system 100. Specifically, movable mirrors 181-186 are respectively secured along three intersecting sides at the upper surfaces of tables 105 and 106.

In addition, four laser interferometers 191-194, which project the measurement lasers to these movable mirrors 181-186 are provided. Laser interferometers 191-194 are arranged along the X direction or the Y direction. Also, laser interferometers 191 and 193 perform positional measurement of tables 105 and 106 positioned in the alignment region A, and laser interferometers 192 and 194 perform positional measurement of tables 105 and 106 positioned in the exposure region E. Note that laser interferometers 191-194 are multiaxis interferometers that have a plurality of optical axes, and measurement of the X, Y and θZ directions is also possible in addition to positional measurement of the XY plane. Also, the output values of the respective optical axes can be independently measured.

In addition, through laser interferometers 191-194, the distance (position information) of tables 105 and 106 in the XY plane is measured, and that measurement information is sent to the control apparatus 50. In addition, in the control apparatus 50, the positions and the like of tables 105 and 106 in the XY plane are obtained. Through this, the position and the like of the wafer W loaded on tables 105 and 106 in the X and Y directions and in the θZ direction is obtained with high accuracy.

Note that a Z direction measurement system that is not shown in the drawing is arranged below tables 105 and 106 for positional measurement of tables 105 and 106 in the Z direction. Positional measurement in the Z direction is only performed at exposure region E and alignment region A discussed below.

Returning to FIG. 1, the control apparatus 50 comprehensively controls the exposure apparatus EX, and it comprises, in addition to a computation part that performs the various computations and control, a memory part, which records the various information, and an input and output part and the like.

In addition, for example, the positions of the reticle R and the wafer W are controlled based on the detection results such as those of laser interferometers 22 and 191-194 and the like provided on the reticle stage 20 and the wafer stage system 100, and the exposure operation which transfers the image of pattern formed on the reticle R to the shot regions on the wafer W is repeatedly performed.

The liquid supply apparatus 81 and the liquid recovery apparatus 82 form a liquid immersion region AR on a portion on the wafer W that includes the projection region of the projection optical system 30 by means of a prescribed liquid L (water) at least while the image of the pattern of the reticle R is being transferred onto the wafer W.

Specifically, the wafer W is exposed in such a way that the liquid L is filled between optical element 32 of the front end part of the projection optical system 30 and the surface of the wafer W by means of the liquid supply apparatus 81, and the image of the pattern of the reticle R is projected onto the wafer W via the projection optical system 30 and the liquid L existing between this projection optical system 30 and the wafer W. Simultaneously, by recovering the liquid L of the liquid immersion region AR by means of the liquid recovery apparatus 82, the liquid L of the liquid immersion region AR is always circulated, and prevention of pollution and temperature control and the like of the liquid L are strictly performed.

In addition, the liquid supply amount and the liquid recovery amount per unit time of the liquid supply apparatus 81 and the liquid recovery apparatus 82 with respect to the surface of the wafer W are controlled by the control apparatus 50.

Note that a synthetic resin such as polytetrafluoroethylene and the like is used to form at least the members through which the liquid L flows among the respective members that form the liquid supply apparatus 81 and the liquid recovery apparatus 82. Through this, it is possible to restrict impurities from being contained in the liquid L.

The air conditioning system (penetration shielding mechanism) 60 is an apparatus for keeping the environmental conditions (cleanliness, temperature, pressure, humidity and the like) of the vicinity of the wafer stage system 100 nearly constant, and the lower end of the projection optical system 30 and the wafer stage system 100 are accommodated in the interior space thereof.

In addition, the air conditioning system 60 comprises a chamber 61, which is installed on top of the floor surface within the clean room, a duct 62 that is connected with the supply port 63 and the exhaust port 64 formed on the chamber 61, and a blower (blower part) 65, which supplies gas G (air) to the interior of the chamber 61. Note that provided on the duct 62 are an air filter AF, which removes particles in the gas G, a chemical filter CF, which removes chemical substances, and a temperature regulation part 66, which regulates the temperature and humidity. The chamber 61 and the duct 62 and the like are formed from a material that has little outgas, such as stainless (SUS) or Teflon (registered trademark).

In addition, due to the fact that the blower 65, the temperature regulation part 66 and the like are controlled by the control apparatus 50, purification, temperature regulation and the like are performed when the gas G within the chamber 61 is circulated via the duct 62, so the environmental conditions within the chamber 61 are kept nearly constant.

In addition, in the configuration of FIG. 1, a configuration, in which the wafer stage system 100 and the lower end of the projection optical system 30 are accommodated within the chamber 61, is used but it is not limited to this. For example, all of the illumination optical system 10, the reticle stage 20, the projection optical system 30, the liquid supply apparatus 81, and the liquid recovery apparatus 82 may be accommodated within the chamber 61, or a portion of these may be accommodated.

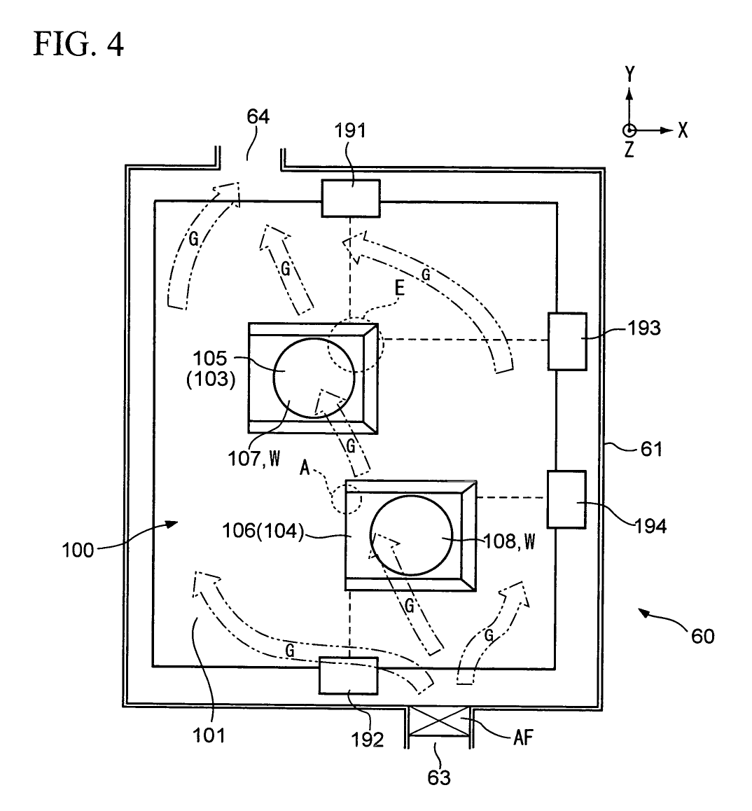

Here, FIG. 4 is a plan view that shows the air conditioning system 60.

The supply port 63 is provided at the side wall (−Y side) of the alignment region A side of the chamber 61. On the other hand, the exhaust port 64 is provided at the side wall (+Y side) of the exposure region E side. Specifically, the supply port 63 and the exhaust port 64 are arranged in opposition so that the alignment region A and the exposure region E are positioned therebetween. Therefore, the configuration is such that, when the air conditioning system 60 has been activated, the gas G within the chamber 61 always flows from the alignment region A side to the exposure region E side.

Note that, though this is omitted from FIG. 1, the illumination optical system 10 and the projection optical system 30 are such that their respective interior spaces are purged by an inert gas (for example, nitrogen, helium and the like), and the reticle stage 20 is also accommodated within a chamber that is not shown in the drawing, and the cleanliness and the like is maintained extremely well.

Next, the method of exposing the image of the pattern of the reticle R onto the wafer W using the aforementioned exposure apparatus EX will be explained. Note that tables 105 and 106 are arranged as shown in FIG. 1, and the wafer W, on which alignment processing has been completed, is mounted on a wafer holder 107 on table 105, and, on the other hand, a wafer W is not mounted on wafer holder 108 on table 106.

First, an X linear motor 111 and a Y linear motor 121 are driven by means of a command of the control apparatus 50 and stage 103 (table 105) on which the wafer W is to be mounted is moved to the exposure region E. Then, in the exposure region E, distance measurement lasers are projected from laser interferometers 191 and 193 toward movable mirrors 181 and 182 arranged on table 105, and the wafer W is moved to the acceleration start position (scan start position) for exposure of the first shot (the first shot region).

Next, the control apparatus 50 operates the liquid supply apparatus 81 to start the supply operation of liquid onto the wafer W. When the liquid supply apparatus 81 is operated, the liquid L is supplied onto the wafer W, and the region between the projection optical system 30 and the wafer W is filled with the liquid L, and a liquid immersion region AR is formed. Then, after the liquid immersion region AR has been formed, the liquid recovery apparatus 82 is also operated to set the supply amount and the recovery amount of the liquid L to approximately the same level or so that the supply amount is slightly higher than the recovery amount, and that status is maintained. By doing so, the liquid immersion region AR is filled with the liquid L at the start of exposure.

Then, after the various exposure conditions are set, Y axis direction scanning of the reticle stage 20 and stage 103 is started, and when the reticle stage 20 and stage 103 are reached the respective target scanning velocities, the pattern region of the reticle R is irradiated by the exposure light EL, and scanning exposure is started. Then, by different pattern regions of the reticle R being sequentially illuminated using exposure light EL and illumination to the entire surface of the pattern region being completed, scanning exposure with respect to the first shot region on the wafer W ends. Through this, the pattern of the reticle R is reduction transferred onto the resist layer of the first shot region on the wafer W via the projection optical system 30 and the liquid L.

When scanning exposure with respect to this first shot region is ended, the control apparatus 50 moves the wafer W gradually by prescribed steps in the X and Y axis directions to move it to the acceleration start position for exposure of the second shot region. That is, an intershot stepping operation is performed. Then, scanning exposure such as that discussed above is performed with respect to the second shot region.

By doing this, scanning exposure of the shot region of the wafer W and stepping operation for exposure of the next shot region are repeatedly performed, and the pattern of the reticle R is sequentially transferred to all shot regions of the wafer W which are to be exposed.

Then, when exposure processing of the wafer W is completed, operation of the liquid supply apparatus 81 is stopped, the amount of the liquid L recovered by the liquid recovery apparatus 82 is increased, and all of the liquid L of the liquid immersion region AR is recovered.

On the other hand, a wafer W is mounted on stage 104 (table 106), on which a wafer W is not mounted, by means of a wafer conveyance apparatus that is not shown in the drawing and is suction held by means of a wafer holder 108. Then, the stage 104 which holds the wafer W is moved to the alignment region A.

Then, in the alignment region A, alignment (enhanced global alignment (EGA) and the like) of the wafer W using an alignment sensor 70 and the like is performed under the control of the control apparatus 50, and the array coordinates of the plurality of shot regions on the wafer W are obtained.

Note that, in the alignment region A, distance measurement lasers are projected from laser interferometers 192 and 194 toward movable mirrors 185 and 186 arranged on table 106, and the position of table 106 is measured with high accuracy.

In this way, a process that performs exposure processing of a wafer W mounted on table 105 and a process that performs mounting and alignment processing of a wafer W on table 106 are independently and simultaneously executed. However, for example, there are also cases in which movement (or alignment processing) of stage 104 (table 106) is restricted (interrupted) through movement of stage 103 (table 105) in the XY direction accompanied by exposure processing.

Then, when exposure processing of the wafer W on table 105 and alignment processing of the wafer W on table 106 are completed, table 105 (stage 103) is moved from the exposure region E to the alignment region A, and, on the other hand, table 106 (stage 104) is moved from the alignment region A to the exposure region E.

Then, exposure processing of the wafer W mounted on table 106 (stage 104) is started. On the other hand, the wafer W mounted on table 105 is unloaded by means of a wafer conveyance apparatus, and, furthermore, a new wafer W is loaded onto table 105, and alignment processing of the new wafer W is started.

In this way, exposure processing of a plurality of wafers W is performed at high throughput by making stage 103 (table 105) and stage 104 (table 106) alternately come and go between the exposure region E and the alignment region A.

In any case, when exposure processing and alignment processing are performed, the gas G within the chamber 61 always flows from the alignment region A toward the exposure region E by the air conditioning system 60. For this reason, the gas G in the vicinity of the exposure region E, whose humidity has increased in conjunction with the liquid immersion region AR being formed, is exhausted to outside the chamber 61 without flowing to the vicinity of the alignment region A. In addition, when tables 103 and 104 (stages 105 and 106) move from the exposure region E to the alignment region A, the liquid L of the liquid immersion regions AR formed on the respective tables 103, 104 is recovered, and drying processing is further implemented, so penetration of the liquid L to the alignment region A, accompanied by the movement of tables 103 and 104, is prevented. Therefore, the environmental conditions surrounding the alignment region A are always kept constant.

In this way, through the exposure apparatus EX of the present invention, the gas G in the vicinity of the exposure region E, whose humidity tends to fluctuate, does not penetrate to the alignment region A, so positional measurement of the wafer W by laser interferometers 192 and 194 in the alignment region A can be accurately performed. Through this, the alignment accuracy of the wafer W is improved, and it is possible to perform pattern exposure in the exposure region well.

Next, a variation of the air conditioning system 60 will be explained.

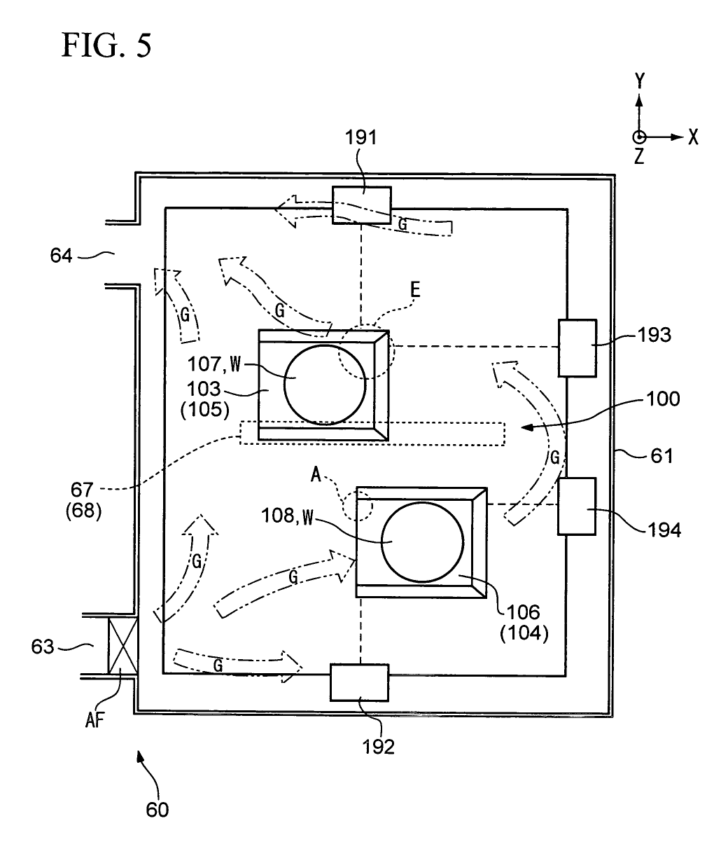

In the embodiment discussed above, the supply port 63 and the exhaust port 64 formed on the chamber 61 are provided on opposing side walls, but it is not limited to this. For example, as shown in FIG. 5, it is also possible to form the supply port 63 and the exhaust port 64 on the same side wall. Furthermore, by providing a shielding plate (shielding part) 67 between the alignment region A and the exposure region E, a flow path, in which the gas G within the chamber 61 flows from the alignment region A toward the exposure region E, may also be formed.

Note that the shielding plate 67 is not limited to a material being, but it may also be an air curtain 68. In the case of an air curtain 68, it is possible to reliably separate the alignment region A and the exposure region E even when it is a wafer stage system 100 with a complex shape, so leakage of gas G is almost entirely eliminated. Also, as in the case in which a shielding plate 67 is provided, there is an advantage in that the shape and the like of the wafer stage system 100 is never restricted.

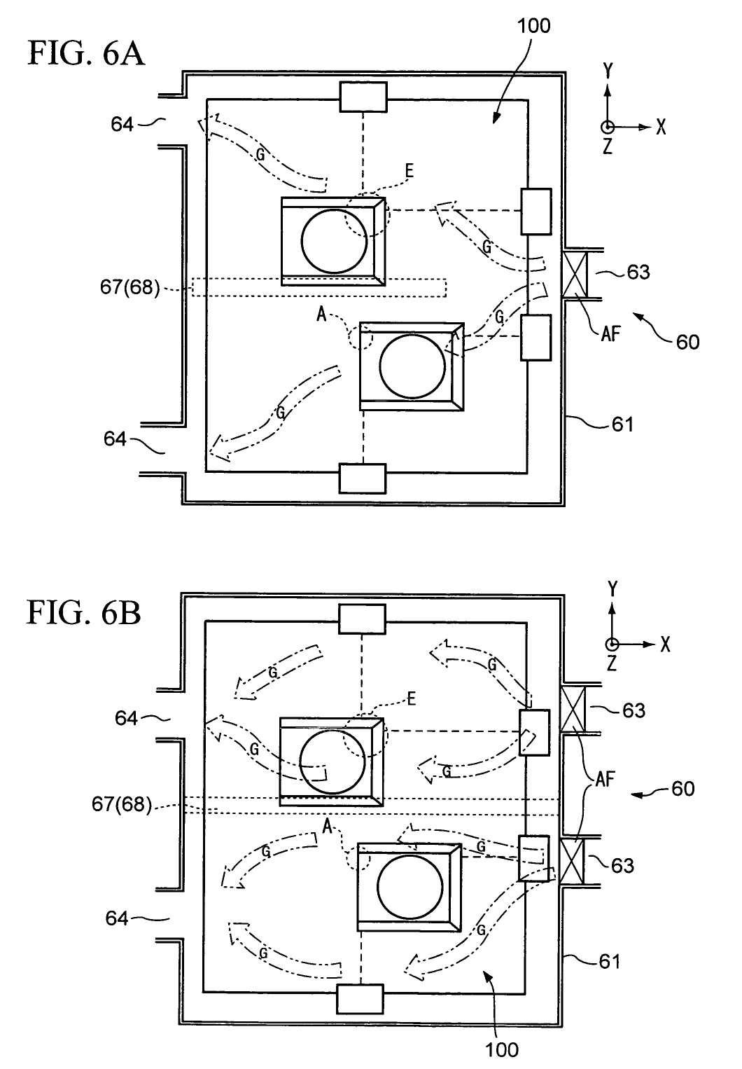

In addition, a plurality of supply ports 63 and exhaust ports 64 may be provided. For example, two exhaust ports 64 are provided as in FIG. 6A, and two pairs of supply port 63 and exhaust port 64 are provided as in FIG. 6B, and a flow path by which the gas G within the chamber 61 flows from the alignment region A toward the exposure region E is formed. In this case as well, it is preferable to provide a shielding plate 67 or an air curtain 68 between the alignment region A and the exposure region E. In the configuration of FIG. 6B, a supply port that supplies gas to the exposure region E and a supply port that supplies gas to the measurement region A are individually provided in the respective regions, so they may be set so that the properties (flow amount, humidity, temperature, constituents and the concentration thereof and the like) of the gas supplied from the respective supply ports are mutually different.

In addition, in the embodiment discussed above, an explanation was given with respect to eliminating the effects of humidity on laser interferometers 192 and 194, which measure the position of the wafer W of the alignment region A, but it is of course also important to eliminate the effects of humidity on laser interferometers 191 and 193, which measure the position of the wafer W of the exposure region E.

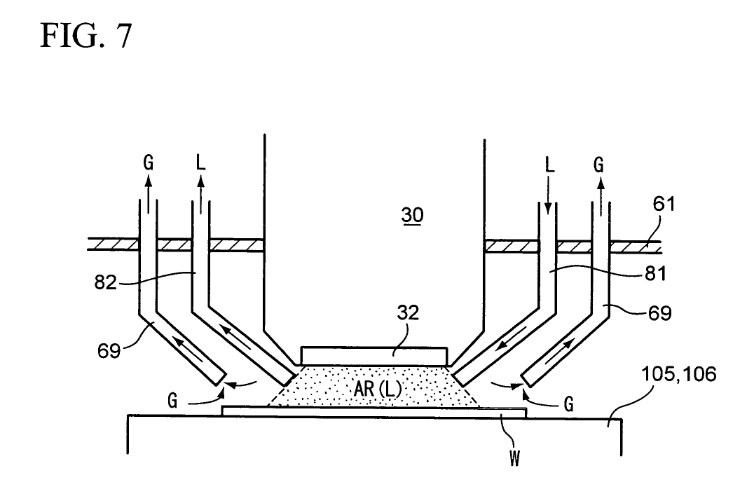

For example, as shown in FIG. 7, by arranging a nozzle-shaped exhaust port 69 in the vicinity of the exposure region E, gas GL whose humidity has increased may be prevented from diffusing within the chamber 61. Exhaust port 69 is connected to a vacuum source and the like that is not shown in the drawing, and gas whose humidity has become high, which is existing in the vicinity of the exposure region E (liquid immersion region AR), is sucked from this exhaust port 69 and exhausted to the exterior of the chamber 61. Through this, it is possible to eliminate the effects on the laser interferometers 191-194, it is also possible to prevent adverse influence on the electrical wiring or the optical elements within the chamber 61 (for example, leakage of electricity and deterioration of optical characteristics due to condensation).

In addition, in the embodiment discussed above, two tables 103, 104 (stages 105 and 106) alternately move the exposure region E and the alignment region A, but, for example, the case may be such that there is one table or there are three or more tables. Also, in addition to the exposure region E and the alignment region A, there may be another region in which positional measurement by the laser interferometers is performed. Even in this case, it is desirable that the gas G in the vicinity of the exposure region E does not penetrate to another region.

Note that the operating procedures indicated in the embodiment discussed above or the various shapes and combinations of the respective component members are only examples, and various changes are possible based on the process conditions and the design requirements within a scope in which there is no deviation from the gist of the present invention. The present invention also includes, for example, following embodiments.

As discussed above, in this embodiment, since ArF excimer laser light is used as the exposure light EL, pure water is supplied as a liquid for liquid immersion exposure. Pure water has advantages in that it can be easily obtained in large quantity at semiconductor fabrication plants and the like and in that it has no adverse effects on the photoresist on the wafer W or on the optical elements (lenses) and the like. In addition, since pure water has no adverse effects on the environment and contains very few impurities, such effects can be expected that the surface of the wafer W and the surface of optical element 32 provided on the front end surface of the projection optical system 30 are cleaned.

In addition, the index of refraction n of pure water (water) with respect to exposure light EL with a wavelength of approximately 193 nm is said to be nearly 1.44. In the case where ArF excimer laser light (193 nm wavelength) is used as the light source of the exposure light EL, on the wafer W, it is possible to shorten the wavelength to 1/n, that is, approximately 134 nm, to obtain high resolution. Also, the depth of focus is expanded by approximately n times, that is, approximately 1.44 times compared with the case in the air.

In addition, it is also possible to use a liquid L that is permeable by the exposure light EL and whose refractive index is as high as possible and that is stable with respect to the photoresist which is coated on the projection optical system 30 or the surface of the wafer W.

For example, if an F2 laser is used as the exposure light source EL, for example, a fluorine group liquid such as a fluorocarbon oil or a perfluoropolyether (PFPE), through which F2 laser light is able to pass, may be used as the liquid L. In this case, it is preferable that lyophilic treatment be performed on the portion that comes into contact with the liquid L by forming, for example, a thin film using a substance with a molecular structure with a low polarity that includes fluorine.

In addition, not only semiconductor wafers for the manufacture of semiconductor devices but glass substrates for display devices, or ceramic wafers for thin film magnetic heads and the like are applicable as the wafer W.

In addition to a step and scan system scanning exposure apparatuses (scanning steppers) that synchronously moves a reticle and a wafer and performs a scanning expose of the pattern of the reticle, a step and repeat system projection exposure apparatuses (steppers) that performs one-shot exposure to the pattern of the reticle in a status that the reticle and the wafer are stationary and sequentially moves the wafer gradually by prescribed steps.

For example, it may be a liquid immersion type stepper provided with a refracting type optical system with a ⅛ magnification ratio. In this case, one-shot exposure of large area chips is not possible, so a stitching (step and stitch) system may also be employed with large area chips.

Note that the configuration of the twin stage type exposure apparatus is not limited to the type of this embodiment. For example, they are disclosed in Japanese Unexamined Patent Application, first Publication No. H10-163099, Japanese Unexamined Patent Application, first Publication No. H10-214783 and U.S. Pat. No. 6,400,441 corresponding thereto, Published Japanese Translation No. 2000-505958 and U.S. Pat. No. 5,699,441 and U.S. Pat. No. 6,262,796 corresponding thereto.

The disclosure of the above publications or U.S. patents is hereby incorporated by reference in its entirety to the extent permitted by the national laws and regulations of the designated states (or elected states) designated by the present international patent application.

The type of exposure apparatus EX is not limited exposure apparatuses that are used in the fabrication of semiconductor devices, in which a semiconductor element pattern is exposed onto a wafer, and it can also be widely applied to exposure apparatuses that are used in the manufacture of liquid crystal display elements and used in the manufacture of displays and exposure apparatuses for the manufacture of thin film magnetic heads, image pickup elements (CCDs), or reticles and masks.

In the case where a linear motor is used in the wafer stage or the reticle stage, an air floating type that uses air bearings or a magnetic levitation type that uses Lorentz's force or reactance force may be used. In addition, the stages may be the types that move along a guide or may be the guideless type in which a guide is not provided. Moreover, in the case where a planar motor is used as the drive apparatus of the stage, one of either a magnet unit (permanent magnet) or an armature unit is connected to the stage, and the other among the magnet unit and the armature unit may be provided on the moving surface side (base) of the stage.

The reaction force generated by the movement of the wafer stage may be mechanically escaped to the floor (ground) using a frame member so that it is not transmitted to the projection optical system, as described in Japanese Unexamined Patent Application, first Publication No. H8-166475 and U.S. Pat. No. 5,528,118 corresponding thereto.

The disclosure of the above publication or U.S. patent is hereby incorporated by reference in its entirety to the extent permitted by the national laws and regulations of the designated states (or elected states) designated by the present international patent application.

The reaction force generated by the movement of the reticle (mask) stage may be caused to mechanically escape to the floor (ground) using a frame member so that it is not transmitted to the projection optical system, as described in Japanese Unexamined Patent Application, first Publication No. H8-330224 and U.S. Pat. No. 5,874,820 corresponding thereto.

The disclosure of the above publication or U.S. patent is hereby incorporated by reference in its entirety to the extent permitted by the national laws and regulations of the designated states (or elected states) designated by the present international patent application.

Note that, if the liquid immersion method is used as discussed above, the number of apertures NA of the projection optical system 30 may at times become 0.9-1.3. In this way, if the number of apertures NA of the projection optical system 30 becomes larger, there are cases in which image formation performance deteriorates due to a polarization effect with the random polarized light conventionally used as the exposure light, so it is preferable that polarized light illumination be used. In that case, linear polarization illumination to match the lengthwise direction of the line pattern of the line and space pattern of the reticle is performed, and diffracted light of the S polarization component (the polarization direction component along the lengthwise direction of the line pattern) may be irradiated from the reticle R pattern in large quantity. In the case in which the space between the projection optical system 30 and the resist coated onto the surface of the wafer W is filled with a liquid, the transmissivity of the diffracted light of the S polarization component at the resist surface, which contributes to the improvement of contrast, is higher than that of the case in which the space between the projection optical system 30 and the resist coated onto the surface of the wafer is filled with gas G (air), so high image formation performance can be obtained even in such cases as when the number of apertures NA of the projection optical system 30 exceeds 1.0. In addition, it is even more effective when a phase shift mask or a grazing-incidence illumination method (particularly, the dipole illumination method) matching the lengthwise direction of the line pattern as disclosed in Japanese Unexamined Patent Application, first Publication No. H6-188169, is arbitrary combined. The disclosure of the above publication is hereby incorporated by reference in its entirety to the extent permitted by the national laws and regulations of the designated states (or elected states) designated by the present international patent application.

In addition, for example, in the case where an ArF excimer laser is used as the exposure light, and a projection optical system 30 with a reduction rate of approximately ¼ is used to expose a fine line and space pattern (for example, L/S of approximately 20-25 nm) on the wafer, depending on the structure of the reticle (for example, the fineness of the pattern and the thickness of the chrome), the reticle acts as a polarization plate due to the Wave guide effect, and more diffracted light of the S polarization component (TM polarization component) is irradiated from the reticle than diffracted light of the P polarization component (TM polarization component), which reduces contrast. In this case as well, it is preferable that a linear polarization illumination as discussed above is used, but even if the reticle were illuminated by random polarized light, it would be possible to obtain high resolution performance using a projection optical system in which the number of apertures NA is large, for example, 0.9-1.3.

In addition, in a case where an extremely fine line and space pattern on the reticle is exposed onto the wafer, there is a possibility that the P polarization component (TM polarization component) will be larger than the S polarization component (TM polarization component) due to the Wave guide effect, but, for example, in the case in which an ArF excimer laser is used as the exposure light, a projection optical system with a reduction rate of approximately ¼ is used to expose a line and space pattern larger than 25 nm on the wafer, more diffracted light of the S polarization component (TM polarization component) is irradiated from the reticle than diffracted light of the P polarization component (TM polarization component), so it would be possible to obtain high resolution performance even in the case in which the number of apertures NA of the projection optical system is large at 0.9-1.3.

In addition, not only linear polarization illumination (S polarization illumination) that matches the lengthwise direction of the line pattern of the reticle but a combination of a polarization illumination method that linearly polarizes in the tangential (circumferential) direction of a circle, of which the optical axis is the center, and the grazing incidence method is also effective. In particular, in the case where not only a line pattern in which the pattern of the reticle extends in a prescribed fixed direction but also a line pattern that extends in a plurality of different directions are intermingled, by jointly using a polarization illumination method that linearly polarizes in the tangential direction of a circle, of which the optical axis is the center, and the annular illumination method, it is possible to obtain high resolution performance even in the case in which the number of apertures NA of the projection optical system is large.

In addition, in the embodiment discussed above, an exposure apparatus that locally fills liquid between the projection optical system and the substrate is employed, but it is also possible to apply the present invention to a liquid immersion exposure apparatus that moves a stage that holds the substrate to be exposed inside a liquid tank and to a liquid immersion exposure apparatus that forms a liquid tank of a prescribed depth on the stage and holds the substrate therein. The structure and the exposure operation of a liquid immersion exposure apparatus that moves a stage that holds the substrate to be exposed inside a liquid tank is disclosed in, for example, Japanese Unexamined Patent Application, first Publication No. H6-124873, and a liquid immersion exposure apparatus that forms a liquid tank of a prescribed depth on the stage and holds the substrate therein is disclosed in, for example, Japanese Unexamined Patent Application, first Publication No. H10-303114 and U.S. Pat. No. 5,825,043. The disclosure of the above publications or U.S. patent is hereby incorporated by reference in its entirety to the extent permitted by the national laws and regulations of the designated states (or elected states) designated by the present international patent application.

In addition, the exposure apparatus which has applied the liquid immersion method discussed above is of a configuration that fills the optical path space of the emergence side of the terminating end optical member of the projection optical system with liquid (pure water) and exposes the wafer W, but, as is disclosed in the PCT International Publication No. WO2004/019128, the optical path space of the incidence side of the terminating end optical member of the projection optical system may also be filled with liquid (pure water). The disclosure of the above publication is hereby incorporated by reference in its entirety to the extent permitted by the national laws and regulations of the designated states (or elected states) designated by the present international patent application.

In the embodiment discussed above, a light transmission type mask, which formed a prescribed light shielding pattern (or phase pattern/light reduction pattern) on a light transmittive substrate, or a light reflecting type mask, which formed a prescribed reflection pattern on a light reflective substrate, was used, but it is not limited to these. For example, instead of those types of masks, an electronic mask (considered as a type of optical system) that forms a transmission pattern, a reflection pattern, or a light emission pattern based on the electronic data of the pattern to be exposed may also be used. This type of electronic mask is disclosed in, for example, U.S. Pat. No. 6,778,257. The disclosure of the above U.S. patent is hereby incorporated by reference in its entirety to the extent permitted by the national laws and regulations of the designated states (or elected states) designated by the present international patent application. Note that the aforementioned electronic mask is a concept that includes both non-emissive image display elements and self-emissive image display elements.

In addition, for example, application to an exposure apparatus that exposes interference fringes produced by the interference of a plurality of beam of lights, such as those known as two-beam interference exposure, onto a substrate is also possible. That type of exposure method and exposure apparatus are disclosed in, for example, PCT International Publication No. WO01/35168. The disclosure of the above publication is hereby incorporated by reference in its entirety to the extent permitted by the national laws and regulations of the designated states (or elected states) designated by the present international patent application.

The exposure apparatus to which the present invention is applied is manufactured by assembling various subsystems, including the respective constituent elements presented in the Scope of Patents Claims of the present application, so that the prescribed mechanical precision, electrical precision, and optical precision are maintained. To ensure these respective precisions, adjustments for achieving optical precision with respect to the various optical systems, adjustments for achieving mechanical precision with respect to the various mechanical systems, and adjustments for achieving electrical precision with respect to the various electrical systems are performed before and after the assembly. The process of assembly from the various subsystems to the exposure apparatus includes mechanical connections, electrical circuit wiring connections, and air pressure circuit piping connections and the like among the various subsystems. Obviously, before the assembly process of these various subsystems to the exposure apparatus, there are the processes of individual assembly of the respective subsystems. When the assembly process of the various subsystems to the exposure apparatuses is ended, overall adjustment is performed, and the various precisions are ensured for the exposure apparatus as a whole. Note that it is preferable that the manufacture of the exposure apparatus is performed in a clean room in which the temperature, the cleanliness and the like are controlled.

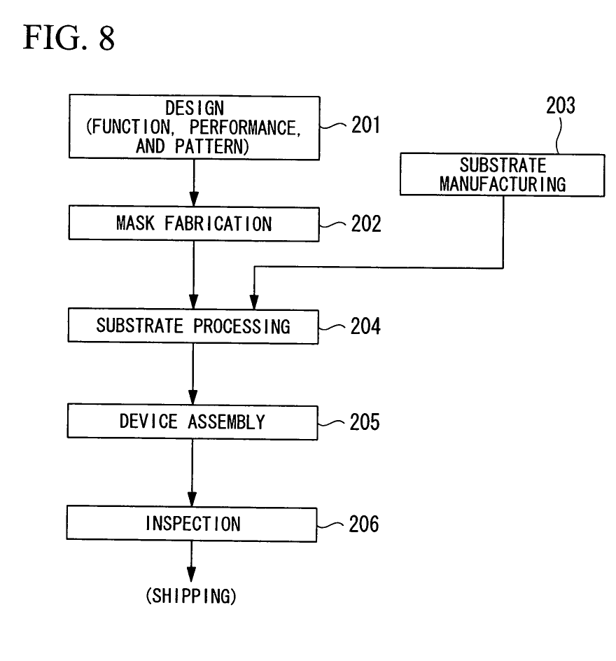

As shown in FIG. 8, microdevices such as semiconductor devices are manufactured by going through a step 201 that performs microdevice function and performance design, a step 202 that fabricates the mask (reticle) based on this design step, a step 203 that manufactures the substrate that is the base material of the device, a substrate processing step 204 that exposes the pattern of the mask onto a substrate by means of the exposure apparatus EX of the embodiment discussed above, a device assembly step (including a dicing process, a bonding process, and a packaging process) 205, and an inspection step 206 and the like.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1-13. (canceled)

14. An exposure apparatus comprising:
an exposure region in which, an optical member is disposed, and in which the substrate is exposed to exposure light via the optical member;
a measurement region in which a sensor is disposed, and in which the substrate is measured using the sensor in advance of exposure at the exposure region;
a movable member that holds the substrate and is movable between the exposure region and the measurement region; and
a prevent device which has a gas flow control member to prevent gas from moving between the exposure region and the measurement region.

15. The exposure apparatus according to claim 14, wherein
the prevent device sets the environment conditions of the exposure region or the measurement region or both regions.

16. The exposure apparatus according to claim 15, wherein
the environment conditions includes cleanliness or temperature or pressure or humidity or any combination of these.

17. The exposure apparatus according to claim 15, wherein the prevent device is an air conditioning device.

18. The exposure apparatus according to claim 14, wherein
the gas flow control member is a barrier disposed between the exposure region and the measurement region.

19. The exposure apparatus according to claim 18, wherein the barrier is an air curtain.

20. The exposure apparatus according to claim 14, wherein
the gas flow control member controls direction of a flow of gas so that movement of the gas between the exposure region and the measurement region is not risen.

21. The exposure apparatus according to claim 20, wherein
the gas flow control member comprises:
a chamber, which includes the exposure region and the measurement region, and
a blower that makes gas within the chamber flow from the measurement region toward the exposure region.

22. The exposure apparatus according to claim 21, wherein
the blower comprises:
an intake port formed on the measurement region, and
an exhaust port formed on the exposure region.

23. The exposure apparatus according to claim 22, wherein
the blower flows gas from the intake port toward the exhaust port along a surface that the movable member moves thereon.

24. The exposure apparatus according to claim 20, wherein
the gas flow control member includes an intake port and an exhaust port that are respectively formed in the exposure region and the measurement region.

25. The exposure apparatus according to claim 14, wherein
the prevent device includes a first gas intake portion disposed in the exposure region and a second gas intake portion disposed in the measurement region, wherein the gas supply of the first and second intake portions are individually controllable.

26. The exposure apparatus according to claim 14, wherein
the prevent device includes a first gas exhaust portion disposed in the exposure region and a second gas exhaust portion disposed in the measurement region, wherein the gas exhaust of the first and second exhaust portions are done individually.

27. The exposure apparatus according to claim 14, wherein
the prevent device includes a suction device that sucks gas of the exposure region.

28. The exposure apparatus according to claim 14, wherein
the prevent device prevents the gas from moving from the exposure region to the measurement region.

29. The exposure apparatus according to claim 28, wherein
the substrate is exposed to the exposure light via a liquid.

30. The exposure apparatus according to claim 29, further comprising:
an immersion device that forms an immersion area partially between the substrate and the optical member.

31. The exposure apparatus according to claim 29, wherein
the prevent device prevents the gas affected by the liquid from moving from the exposure region to the measurement region.

32. The exposure apparatus according to claim 14, further comprising:
a second movable member that is disposed in the same space of the movable member and is movable independently from the movable member.

33. The exposure apparatus according to claim 32, wherein
the second movable member can hold a substrate.

34. The exposure apparatus according to claim 32, wherein
the movable member and the second movable member move on a same base.

35. A device manufacturing method that includes a lithography process, wherein
an exposure apparatus of claim 14 is used in the lithography process.

36. An exposure apparatus comprising:
an exposure region in which an optical member is disposed, and in which the substrate is exposed to exposure light via the optical member;
a measurement region in which a sensor is disposed, and in which the substrate is measured using the sensor in advance of exposure at the exposure region;
a movable member that holds the substrate and is movable between the exposure region and the measurement region; and
a supply device which includes a first gas intake portion disposed in the exposure region and a second gas intake portion disposed in the measurement region, wherein the gas supply of the first and second intake portions are individually controllable.

37. The exposure apparatus according to claim 36, wherein
the properties of the gas supplied from the first gas intake portion and the gas supplied from the second gas intake portion are mutually different.

38. The exposure apparatus according to claim 36, wherein
an exhaust port is respectively formed in the exposure region and the measurement region.

39. The exposure apparatus according to claim 36, wherein
the intake device supplies a gas so that the environmental condition of the exposure region or the measurement region or both regions are set to the predetermined state.

40. The exposure apparatus according to claim 39, wherein
the environment conditions includes cleanliness or temperature or pressure or humidity or any combination of these.

41. The exposure apparatus according to claim 36, wherein
the supply device prevents the gas from moving from the exposure region to the measurement region.

42. The exposure apparatus according to claim 41, wherein
the substrate is exposed to the exposure light via a liquid.

43. The exposure apparatus according to claim 42, further comprising:
an immersion device that forms an immersion area partially between the substrate and the optical member.

44. The exposure apparatus according to claim 42, wherein
the supply device prevents the gas affected by the liquid from moving from the exposure region to the measurement region.

45. The exposure apparatus according to claim 36, further comprising:
a second movable member that is disposed in the same space of the movable member and is movable independently from the movable member.

46. The exposure apparatus according to claim 45, wherein
the second movable member can hold a substrate.

47. The exposure apparatus according to claim 45, wherein
the movable member and the second movable member move on a same base.

48. A device manufacturing method that includes a lithography process, wherein
an exposure apparatus of claim 36 is used in the lithography process.

49. An exposure apparatus comprising:
an exposure region in which an optical member is disposed, and in which the substrate is exposed to exposure light via the optical member;
a measurement region in which a sensor is disposed, and in which the substrate is measured using the sensor in advance of exposure at the exposure region;
a movable member that holds the substrate and is movable between the exposure region and the measurement region; and
an exhaust device which includes a first gas exhaust portion disposed in the exposure region and a second gas exhaust portion disposed in the measurement region, wherein the gas exhaust of the first and second exhaust portions are done individually.

50. The exposure apparatus according to claim 49, further comprising:
a supply device that supplies gas to the exposure region and to the measurement region.

51. The exposure apparatus according to claim 49, wherein
the exhaust device prevents the gas from moving from the exposure region to the measurement region.

52. The exposure apparatus according to claim 51, wherein
the substrate is exposed to the exposure light via a liquid.

53. The exposure apparatus according to claim 52, further comprising:
an immersion device that forms an immersion area partially between the substrate and the optical member.

54. The exposure apparatus according to claim 52, wherein
the exhaust device prevents the gas affected by the liquid from moving from the exposure region to the measurement region.

55. The exposure apparatus according to claim 49, further comprising:
a second movable member that is disposed in the same space of the movable member and is movable independently from the movable member.

56. The exposure apparatus according to claim 55, wherein
the second movable member can hold a substrate.

57. The exposure apparatus according to claim 55, wherein
the movable member and the second movable member move on a same base.

58. A device manufacturing method that includes a lithography process, wherein
an exposure apparatus of claim 49 is used in the lithography process.

59. An exposure method comprising:
measuring a substrate retained on a movable member at an measuring region;
moving, after the measurement, the substrate retained on the movable member from the measurement region to an exposure region; and
preventing gas from moving between the exposure region and the measurement region.

60. The method according to claim 59, wherein
preventing gas from moving by using a device that sets the environment conditions of the exposure region or the measurement region or both regions.

61. The method according to claim 60, wherein
the environment conditions includes cleanliness or temperature or pressure or humidity or any combination of these.

62. The method according to claim 60, wherein
the device includes an air conditioning device.

63. The method according to claim 59, wherein
preventing gas from moving includes providing a barrier between the exposure region and the measurement region.

64. The method according to claim 63, wherein
the barrier is an air curtain.

65. The method according to claim 59, wherein
preventing gas from moving includes controlling direction of a flow of gas so that movement of the gas between the exposure region and the measurement region is not risen.

66. The method according to claim 65, wherein
controlling direction of the flow of gas comprises:
providing a chamber, which includes the exposure region and the measurement region, and
flowing gas within the chamber from the measurement region toward the exposure region.

67. The method according to claim 66, wherein
controlling direction of the flow of gas includes providing an intake port at the measurement region and an exhaust port at the exposure region.

68. The method according to claim 67, wherein
flowing gas from the intake port to the exhaust port along a surface that the movable member moves thereon.

69. The method according to claim 65, wherein
preventing gas from moving includes providing an intake port and an exhaust port at the exposure region and the measurement region respectively.

70. The method according to claim 59, wherein
preventing gas from moving comprises:
providing a first gas intake portion at the exposure region;
providing a second gas intake portion at the measurement region; and
supplying gas from the first and second intake portions by controlling individually.

71. The method according to claim 59, wherein
preventing gas from moving includes exhausting from a first gas exhaust portion disposed in the exposure region and from a second gas exhaust portion disposed in the measurement region individually.

72. The method according to claim 59, wherein
preventing gas from moving includes sucking gas of the exposure region.

73. The method according to claim 59, wherein
preventing gas from moving is preventing gas from moving from the exposure region to the measurement region.

74. The method according to claim 73, further comprising:
exposing the substrate to exposure light via a liquid at the exposure region.

75. The method according to claim 74, further comprising:
forming an immersion area partially between the substrate and an optical member that irradiates the exposure light.

76. The method according to claim 74, wherein
preventing gas from moving includes preventing gas affected by the liquid from moving from the exposure region to the measurement region.

77. The method according to claim 59, further comprising:
providing a second movable member that is disposed in the same space of the movable member and is movable independently from the movable member.

78. The method according to claim 77, wherein
retaining a substrate by the second movable member.

79. The method according to claim 77, wherein
moving the movable member and the second movable member on a same base.

80. A device manufacturing method that includes a lithography process, wherein
an exposure method of claim 59 is used in the lithography process.

81. An exposure method comprising:
measuring a substrate retained on a movable member at an measuring region;
moving, after the measurement, the substrate retained on the movable member from the measurement region to an exposure region;
supplying gas to the exposure region from a first gas intake portion disposed in the exposure region; and
supplying gas to the measurement region from a second gas intake portion disposed in the measurement portion, wherein
the gas supply of the first gas intake portion and the gas supply of the second gas intake portion are individually controllable.

82. The method according to claim 81, wherein
the properties of the gas supplied from the first gas intake portion and the gas supplied from the second gas intake portion are mutually different.

83. The method according to claim 81, further comprising:
providing an exhaust port at the exposure region and the measurement region respectively.

84. The method according to claim 81, wherein
supplying the gas so that the environmental condition of the exposure region or the measurement region or both regions are set to the predetermined state.

85. The method according to claim 84, wherein
the environment conditions includes cleanliness or temperature or pressure or humidity or any combination of these.

86. The method according to claim 79, further comprising:
preventing gas from moving from the exposure region to the measurement region.

87. The method according to claim 86, further comprising:
exposing the substrate to exposure light via a liquid at the exposure region.

88. The method according to claim 87, further comprising:
forming an immersion area partially between the substrate and an optical member that irradiates the exposure light.

89. The method according to claim 87, wherein
preventing gas from moving includes preventing gas affected by the liquid from moving from the exposure region to the measurement region.

90. The method according to claim 81, further comprising:
providing a second movable member that is disposed in the same space of the movable member and is movable independently from the movable member.

91. The method according to claim 90, wherein
retaining a substrate by the second movable member.

92. The method according to claim 90, wherein
moving the movable member and the second movable member on a same base.

93. A device manufacturing method that includes a lithography process, wherein
an exposure method of claim 81 is used in the lithography process.

94. An exposure method comprising:
measuring a substrate retained on a movable member at an measuring region;
moving, after the measurement, the substrate retained on the movable member from the measurement region to an exposure region; and
exhausting from a first gas exhaust portion disposed in the exposure region and from a second gas exhaust portion disposed in the measurement region individually.

95. The method according to claim 94, further comprising:
supplying gas to the exposure region and to the measurement region by using a same supply device.

96. The method according to claim 94, further comprising:
preventing gas from moving from the exposure region to the measurement region.

97. The method according to claim 96, further comprising:
exposing the substrate to exposure light via a liquid at the exposure region.

98. The method according to claim 97, further comprising:
forming an immersion area partially between the substrate and an optical member that irradiates the exposure light.

99. The method according to claim 97, wherein
preventing gas from moving includes preventing gas affected by the liquid from moving from the exposure region to the measurement region.

100. The method according to claim 94, further comprising:
providing a second movable member that is disposed in the same space of the movable member and is movable independently from the movable member.

101. The method according to claim 100, wherein
retaining a substrate by the second movable member.

102. The method according to claim 100, wherein
moving the movable member and the second movable member on a same base.

103. A device manufacturing method that includes a lithography process, wherein
an exposure method of claim 94 is used in the lithography process.

104. An exposure apparatus comprising:
an exposure region for exposing a substrate to exposure light;
a measurement region for measuring the substrate in advance of exposure at the exposure region;
movable means for holding the substrate and for moving it between the exposure region and the measurement region; and
prevent means for preventing gas from moving between the exposure region and the measurement region.

105. A method for manufacturing an exposure apparatus comprising:
providing an exposure region in which, an optical member is disposed, and in which the substrate is exposed to exposure light via the optical member;
providing a measurement region in which a sensor is disposed, and in which the substrate is measured using the sensor in advance of exposure at the exposure region;
providing a movable member that holds the substrate and is movable between the exposure region and the measurement region; and
providing a prevent device which has a gas flow control member to prevent gas from moving between the exposure region and the measurement region.

106. An exposure apparatus comprising:
an exposure region for exposing a substrate to exposure light;
a measurement region for measuring the substrate in advance of exposure at the exposure region;
movable means for holding the substrate and for moving it between the exposure region and the measurement region; and
supply means including first gas intake means for supplying gas to the exposure region and second gas intake means for supplying gas to the measurement region, wherein the gas supply of the first and second intake means are individually controllable.

107. A method for manufacturing an exposure apparatus comprising:
providing an exposure region in which an optical member is disposed, and in which the substrate is exposed to exposure light via the optical member;
providing a measurement region in which a sensor is disposed, and in which the substrate is measured using the sensor in advance of exposure at the exposure region;
providing a movable member that holds the substrate and is movable between the exposure region and the measurement region; and
providing a supply device which includes a first gas intake portion disposed in the exposure region and a second gas intake portion disposed in the measurement region, wherein the gas supply of the first and second intake portions are individually controllable.

108. An exposure apparatus comprising:
an exposure region for exposing a substrate to exposure light;
a measurement region for measuring the substrate in advance of exposure at the exposure region;
movable means for holding the substrate and for moving it between the exposure region and the measurement region; and
exhaust means including first gas exhaust means for exhausting gas from the exposure region and second gas exhaust means for exhausting gas from the measurement region, wherein the gas exhaust of the first and second exhaust means are individually.

109. A method for manufacturing an exposure apparatus comprising:
providing an exposure region in which an optical member is disposed, and in which the substrate is exposed to exposure light via the optical member;
providing a measurement region in which a sensor is disposed, and in which the substrate is measured using the sensor in advance of exposure at the exposure region;
providing a movable member that holds the substrate and is movable between the exposure region and the measurement region; and
providing an exhaust device which includes a first gas exhaust portion disposed in the exposure region and a second gas exhaust portion disposed in the measurement region, wherein the first and second exhaust portions are individually exhaust gas in the exposure region and gas in the measurement region respectively.
